(19) United States
(12) Patent Application Publication
(10) Pub. No.: US 2022/0043071 A1
(43) Pub. Date: Feb. 10, 2022

(54) TESTING DEVICE FOR EMERGENCY LIGHTING EQUIPMENT

(71) Applicant: Wentai Technology Corporation, New Taipei City (TW)

(72) Inventor: Yun-Yuan YEH, New Taipei City (TW)

(21) Appl. No.: 17/091,257

(22) Filed: Nov. 6, 2020

(30) Foreign Application Priority Data
Aug. 4, 2020 (TW) 109210031

(51) Int. Cl. G01R 31/44; H02J 9/06

(52) U.S. Cl. CPC G01R 31/44; H02J 9/065

(57) ABSTRACT

A testing device for emergency lighting equipment including a main control unit and at least one control module, where each of the at least one control module is used to check operational readiness of an emergency lighting device, and the main control unit and the at least one control module are all connected to a network to form a control system for a smart phone or a building security monitoring system to perform a remote inspection operation on at least one aforementioned emergency lighting device via the network.

### BACKGROUND OF THE INVENTION

### Field of the Invention

The present invention relates to an inspection device for emergency lighting equipment, especially to a device that can quickly check whether the emergency lighting equipment is normal.

### Description of the Related Art

Please refer to FIG. 1, which is a schematic diagram of a conventional emergency lighting device. As shown in FIG. 1, a conventional emergency lighting device 10 is located on a wall 20 of a stairwell and is connected to an AC (alternating current) power socket 21 located at a height of the wall 20.

The conventional emergency lighting device 10 is usually powered by an AC power source, and must be automatically lit in the event of a power failure. However, it is impossible to judge by appearance whether the battery, the control circuit and the lamp inside the conventional emergency lighting device 10 are all normally functioning, and it will be too late to discover that the conventional emergency lighting device 10 is malfunctioning when a power outage occurs. Therefore, it is necessary to regularly inspect the conventional emergency lighting device 10 and maintain the readiness of the conventional emergency lighting device 10, so as to ensure that the conventional emergency lighting device 10 will be lit immediately to provide emergency lighting when a power outage takes place.

In addition, although the official firefighting units have the duty to regularly conduct inspections on emergency exit signs and emergency lighting devices, however, as there are gaps between the inspections, the emergency exit signs and emergency lighting devices cannot be guaranteed to be normal every day. Moreover, for each inspection, a switch in the power box must be operated to power off the emergency lighting device 10 to confirm whether the emergency lighting device 10 is normal in providing emergency lighting, which is not only time-consuming and labor-intensive, but also inefficient.

To solve the above problems, a novel testing device for emergency lighting equipment is needed.

### SUMMARY OF THE INVENTION

The main objective of the present invention is to provide a testing device that can detect the state of at least one emergency lighting device by a remote control, or detect the state of an emergency lighting device by a near wireless control, so as to quickly complete inspection operations of multiple emergency lighting devices located in different areas.

To achieve the above objectives, a testing device for emergency lighting equipment is proposed, which has a main control unit and at least one control module, where each of the at least one control module is used to check operational readiness of an emergency lighting device, and the main control unit and the at least one control module are all connected to a network to form a control system for a smart phone or a building security monitoring system to perform a remote inspection operation on at least one aforementioned emergency lighting device via the network, the testing device being characterized in that:

the main control unit is used to receive commands from the smart phone or the building security monitoring system to drive at least one aforementioned control module to perform a remote inspection operation on at least one aforementioned emergency lighting device via the network, and receive an inspection result of each aforementioned remote inspection operation and transmit each aforementioned inspection result to the smart phone or the building security monitoring system via the network; and

each aforementioned control module has a switch controller and a switch coupled with the switch controller to drive one aforementioned emergency lighting device to be disconnected from an alternating current power source, and thereby make a battery inside the emergency lighting device to start to supply power to make the emergency lighting device provide a lighting state, the switch controller has a light sensing unit to detect the lighting state, and the switch controller generates the inspection result according to the lighting state.

In possible embodiments, the network can be a local area network or an Internet.

In one embodiment, the switch controller has:

a network connection interface for connecting with the network; and

a control circuit coupled with the network connection interface and the light sensing unit, and having an output terminal to output a switch signal to one aforementioned switch.

In one embodiment, the switch controller further has:

a wireless communication unit and an antenna coupled with the wireless communication unit, and the control circuit performs a wireless communication with the smart phone via the wireless communication unit and the antenna.

In possible embodiments, the wireless communication can be infrared communication, RF communication, WiFi communication, Bluetooth communication, or ZigBee communication.

In one embodiment, the wireless communication adopts an encoding rule.

In one embodiment, the switch is a relay.

In one embodiment, the emergency lighting device has a lighting function and an escape instruction text or pattern.

In one embodiment, the smart phone provides an operating interface on a display for a user to perform at least one aforementioned remote inspection operation and view at least one aforementioned inspection result.

In possible embodiments, the switch controller can be powered by an alternating current power source or a secondary battery.

### BRIEF DESCRIPTION OF THE DRAWINGS

FIG. 1 is a schematic diagram of a conventional emergency lighting device.

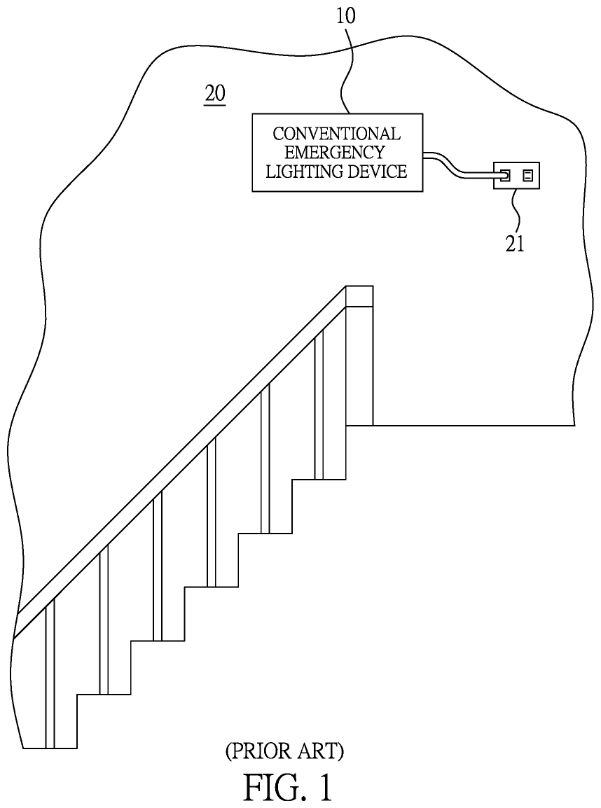

FIG. 2 illustrates a block diagram of an embodiment of the testing device for emergency lighting equipment of the present invention.

FIG. 3 illustrates a block diagram of an embodiment of the switch controller of the testing device for emergency lighting equipment of FIG. 2.

### DETAILED DESCRIPTION OF THE PREFERRED EMBODIMENTS

The principle of the present invention lies in: let a switch device having a light sensing function be coupled between an alternating current power source and an emergency lighting device, and make the switch device have two control modes of a remote control and a near wireless control to facilitate inspectors to perform inspection operations on the emergency lighting equipment.

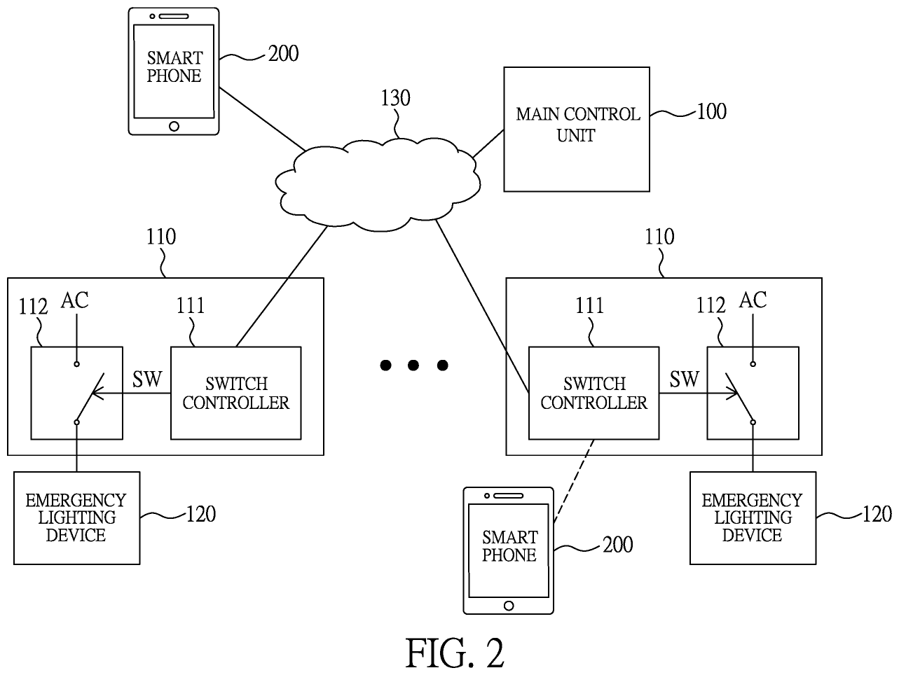

Please refer to FIG. 2, which illustrates a block diagram of an embodiment of the testing device for emergency lighting equipment of the present invention. As shown in FIG. 2, the testing device for emergency lighting equipment includes a main control unit 100 and at least one control module 110, where each control module 110 has a switch controller 111 and a switch 112 to control the power-on of an emergency lighting device 120, and the main control unit 100 and each control module 110 are connected to a network 130 to form a control system for a smart phone 200 (or a building security monitoring system) to perform remote inspection operations via the network 130. In addition, the smart phone 200 can also directly operate a control module 110 via a wireless communication to perform an inspection operation on the emergency lighting device 120.

The main control unit 100 is used to receive commands from a smart phone 200 (or a building security monitoring system) via the network 130 to perform remote inspection operations on at least one control module 110 and receive the results of the inspection operations provided by the at least one control module 110 via the network 130, and transmit the results to the smart phone 200 (or the building security monitoring system). In addition, the smart phone 200 (or the building security monitoring system) can be provided with an operating interface for an inspector to select at least one control module 110 for remote inspection operations and view the results of the inspection operations.

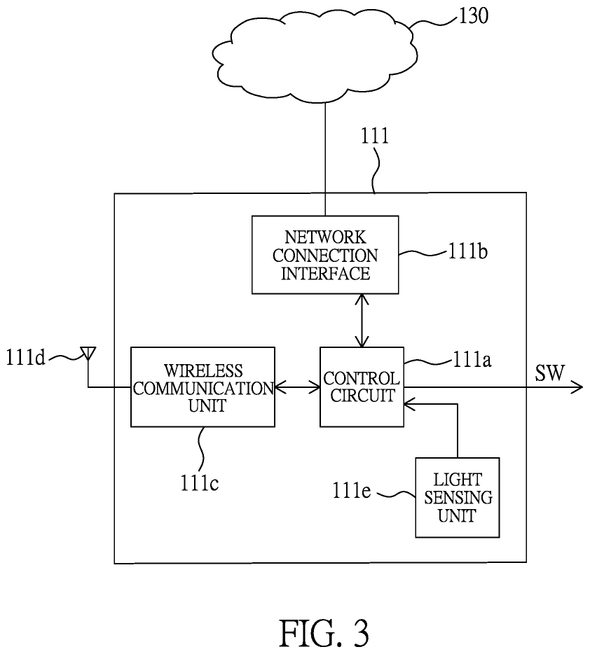

Please refer to FIG. 3, which illustrates a block diagram of an embodiment of the switch controller of the testing device for emergency lighting equipment of FIG. 2. As shown in FIG. 3, the switch controller 111 has a control circuit 111a, a network connection interface 111b, a wireless communication unit 111c, an antenna 111d, and a light sensing unit 111e.

The control circuit 111a is coupled with the network connection interface 111b, the wireless communication unit 111c and the light sensing unit 111e, where the control circuit 111a is connected to the network 130 in a wired or wireless manner through the network connection interface 111b, and the network 130 can be a local area network or an Internet; the control circuit 111a can directly receive commands from a smart phone 200 and transmit an inspection result to the smart phone 200 via the wireless communication unit 111c and the antenna 111d; the control circuit 111a receives a lighting state of an emergency lighting device 120 through the light sensing unit 111e; and the control circuit 111a controls the conduction (on or off) of the switch 112 by sending a switch signal SW to the switch 112, and thereby controls the connection of an alternating current power AC with the emergency lighting device 120. In addition, the wireless communication unit 111c uses a wireless communication, which can be infrared communication, RF communication, WiFi communication, Bluetooth communication, or ZigBee communication, to form a local area network to communicate with the smart phone 200, and the wireless communication can adopt an encoding rule.

In addition, each switch controller 111 can be powered by an alternating current power source AC or a secondary battery.

In addition, the switch 112 can be a relay, which has an input terminal, a control terminal and an output terminal, the input terminal being used to couple with the alternating current power source AC, and the control terminal being coupled with the control circuit 111a to receive and respond to the switch signal SW to determine whether to connect the alternating current power source AC to an emergency lighting device 120 via the output terminal. In addition, the control terminal can have a manual control terminal for an operator to manually determine whether to connect the alternating current power source AC to the emergency lighting device 120 via the output terminal.

The emergency lighting device 120 has a lamp, and preferably, has a lighting function and an escape instruction text or pattern.

When in operation, an operator can select at least one control module 110 through the operation interface on the smart phone 200 (or a building security monitoring system) for remote inspection operations, and use the operation interface to view the results of the inspection operations; or use the wireless communication module in the smart phone 200 (or a building security monitoring system) to directly communicate with the wireless communication unit 111c of a control module 110 to drive the control module 110 to perform an inspection operation. When a control module 110 is selected, its switch controller 111 will drive the switch 112 to be in open status to cause the internal battery of the emergency lighting device 120 to power the emergency lighting device 120 to provide emergency lighting. Besides, the light sensing unit 111e will feed back a lighting state (brightness) of the emergency lighting device 120 to the control circuit 111a, and the control circuit 111a will generate an operation state judgment result (normal status or failed status) based on the comparison of the lighting state (brightness) with a threshold, and transmit the operation state judgment result (normal status or failed status) to a smart phone 200 (or the building security monitoring system) via the network connection interface 111b or the wireless communication unit 111c to inform the operator about the current state of the emergency lighting device 120, in which, when the lighting state (brightness) is greater than the threshold, the operation state judgment result will present a content representing the normal status, and when the lighting state (brightness) is not greater than the threshold, the operation state judgment result will present a content representing the failed status. After learning the current state of the emergency lighting device 120, the operator can press a reset button icon to notify the control module 111 to turn on the corresponding switch 112 to reconnect the corresponding emergency lighting device 120 to the alternating current power source AC.

Thanks to the arrangements mentioned above, the present invention possesses the following advantages:

The testing device of the present invention can detect the state of at least one emergency lighting device by a remote control, or detect the state of an emergency lighting device by a near wireless control, so as to quickly complete inspection operations of multiple emergency lighting devices located in different areas.

While the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance over the conventional structure and further complies with the patent application requirements and is submitted to the Patent and Trademark Office for review and granting of the commensurate patent rights.

What is claimed is:

1. A testing device for emergency lighting equipment, which has a main control unit and at least one control module, where each of the at least one control module is used to check operational readiness of an emergency lighting device, and the main control unit and the at least one control module are all connected to a network to form a control system for a smart phone or a building security monitoring system to perform a remote inspection operation on at least one said emergency lighting device via the network, the testing device being characterized in that:
the main control unit is used to receive commands from the smart phone or the building security monitoring system to drive at least one said control module to perform a remote inspection operation on at least one said emergency lighting device via the network, and receive an inspection result of each said remote inspection operation and transmit each said inspection result to the smart phone or the building security monitoring system via the network; and
each said control module has a switch controller and a switch coupled with the switch controller to drive one said emergency lighting device to be disconnected from an alternating current power source, and thereby make a battery inside the emergency lighting device to start to supply power to make the emergency lighting device provide a lighting state, the switch controller has a light sensing unit to detect the lighting state, and the switch controller generates the inspection result according to the lighting state.

2. The testing device for emergency lighting equipment as disclosed in claim 1, wherein the network is a local area network or an Internet.

3. The testing device for emergency lighting equipment as disclosed in claim 1, wherein the switch controller includes:
a network connection interface for connecting with the network; and
a control circuit coupled with the network connection interface and the light sensing unit, and having an output terminal to output a switch signal to one said switch.

4. The testing device for emergency lighting equipment as disclosed in claim 3, wherein the switch controller further includes:
a wireless communication unit and an antenna coupled with the wireless communication unit, and the control circuit performs a wireless communication with the smart phone via the wireless communication unit and the antenna.

5. The testing device for emergency lighting equipment as disclosed in claim 4, wherein the wireless communication is selected from a group consisting of infrared communication, RF communication, WiFi communication, Bluetooth communication, and ZigBee communication.

6. The testing device for emergency lighting equipment as disclosed in claim 5, wherein the wireless communication adopts an encoding rule.

7. The testing device for emergency lighting equipment as disclosed in claim 1, wherein the switch is a relay.

8. The testing device for emergency lighting equipment as disclosed in claim 1, wherein the emergency lighting device has a lighting function and an escape instruction text or pattern.

9. The testing device for emergency lighting equipment as disclosed in claim 8, wherein the smart phone provides an operating interface on a display for a user to perform at least one said remote inspection operation and view at least one said inspection result.

10. The testing device for emergency lighting equipment as disclosed in claim 1, wherein the switch controller is powered by an alternating current power source or a secondary battery.
